(19) United States
(12) Patent Application Publication
(10) Pub. No.: US 2013/0049218 A1
(43) Pub. Date: Feb. 28, 2013

(54) SEMICONDUCTOR DEVICE PACKAGING HAVING PRE-ENCAPSULATION THROUGH VIA FORMATION

(71) Applicants: Zhiwei Gong, Chandler, AZ (US); Navjot Chhabra, Austin, TX (US); Glenn G. Daves, Austin, TX (US); Scott M. Hayes, Chandler, AZ (US)

(72) Inventors: Zhiwei Gong, Chandler, AZ (US); Navjot Chhabra, Austin, TX (US); Glenn G. Daves, Austin, TX (US); Scott M. Hayes, Chandler, AZ (US)

(21) Appl. No.: 13/222,150

(22) Filed: Aug. 31, 2011

(51) Int. Cl. H01L 21/77; H01L 21/56; H01L 23/48

(52) U.S. Cl. 257/774; 438/107; 438/127; 257/E23.011; 257/E21.598; 257/E21.502

(57) ABSTRACT

A method for forming signal conduits before encapsulation for incorporation as through vias in a semiconductor device package is provided. One or more signal conduits are formed through photolithography and metal deposition on a metal film or substrate. After removing photoresistive material, the semiconductor device package is built by encapsulating the signal conduits along with any semiconductor die and other parts of the package. The ends of the signal conduits are exposed and the signal conduits can then be used as through vias, providing signal-bearing pathways between interconnects or contacts on the bottom and top of the package, and electrical contacts of the semiconductor die. Using this method, signal conduits can be provided in a variety of geometric placings in the semiconductor device package. A semiconductor device package including the signal conduits made from the above method is also provided.

### CROSS-REFERENCE TO RELATED APPLICATIONS

This application is related to U.S. patent application Ser. No. ______ (Attorney Docket No. MT11599ZK), filed on even date, entitled “SEMICONDUCTOR DEVICE PACKAGING HAVING PRE-ENCAPSULATION THROUGH VIA FORMATION USING LEAD FRAMES WITH ATTACHED SIGNAL CONDUITS,” naming Zhiwei Gong, Navjot Chhabra, Glenn G. Daves, and Scott M. Hayes as inventors, and assigned to the current assignee hereof and U.S. patent application Ser. No. ______ (Attorney Docket No. MT1600ZK), filed on even date, entitled “SEMICONDUCTOR DEVICE PACKAGING HAVING PRE-ENCAPSULATION THROUGH VIA FORMATION USING DROP-IN SIGNAL CONDUITS,” naming Zhiwei Gong, Navjot Chhabra, Glenn G. Daves, and Scott M. Hayes, Douglas G. Mitchell, and Jason R. Wright as inventors, and assigned to the current assignee hereof.

### BACKGROUND

1. Field

This disclosure relates generally to semiconductor device packaging, and more specifically, to providing through-package vias in an encapsulated device package by forming signal conduits prior to the encapsulation process.

2. Related Art

Semiconductor and other types of electronic devices are often encapsulated wholly or partly in resin to provide environmental protection and facilitate external connection to the devices. Subsequent to encapsulation, interconnect structures can be built up on one or both sides of the encapsulated devices. For packages having electrical contacts on both top and bottom surfaces (e.g., a double-sided buildup), through-vias are often made to provide contacts between bottom side and top side interconnect structures. Traditionally, through package vias are made after encapsulation using a drilling and filling/metallization process that includes steps for via drill, via fill/metallization, polish and taping, and so on. This process of post-encapsulation via formation introduces complexities to the manufacturing process that have a variety of manufacturing and reliability challenges (e.g., consistent integrity of the through via and reliable connection to the interface). Further, costs associated with materials, processes and additional tooling to generate the through vias can be high.

It is therefore desired to have a process for creation of through package vias before encapsulation. It is further desired that the mechanism for providing through vias allows for formation of the through via using photolithographic processes similar to package buildup technology.

### BRIEF DESCRIPTION OF THE DRAWINGS

The present invention may be better understood, and its numerous objects, features, and advantages made apparent to those skilled in the art by referencing the accompanying drawings.

FIG. 1 is a simplified block diagram illustrating a perspective view of an assembly having signal conduits formed on a metal film or other substrate, in accord with one embodiment of the present invention.

FIG. 2 is a simplified block diagram illustrating a plating process for forming electrically-conductive signal conduits on the assembly, in accord with one embodiment of the present invention.

FIG. 3 is a simplified block diagram illustrating the cross sectional view of the assembly at a later stage in processing, according to one embodiment of the present invention.

FIG. 4 is a simplified block diagram illustrating the cross sectional view of the assembly at a later stage in processing, according to an embodiment of the present invention.

FIG. 5 is a simplified block diagram illustrating a cross-sectional view of the assembly at a later stage in processing, according to an embodiment of the present invention.

FIG. 6 is a simplified block diagram illustrating a cross sectional view of a device structure incorporating the assembly at a stage in an example of processing in accord with an embodiment of the present invention.

FIG. 7 is a simplified block diagram illustrating cross sectional view of the device structure at a later stage of processing, according to an embodiment of the present invention.

FIG. 8 is a simplified block diagram illustrating the cross sectional view of the device structure at a later stage of processing, according to an embodiment of the present invention.

FIG. 9 is a simplified block diagram illustrating the cross sectional view of the device structure at a later stage of processing, according to an embodiment of the present invention.

FIG. 10 is a simplified block diagram illustrating a cross sectional view of the device structure after buildup, ball placement and singulation, according to an embodiment of the present invention.

The use of the same reference symbols in different drawings indicates identical items unless otherwise noted. The figures are not necessarily drawn to scale.

### DETAILED DESCRIPTION

A method for forming signal conduits before encapsulation for incorporation as through vias in a semiconductor device package is provided. One or more signal conduits are formed through photolithography and metal deposition on a metal film or substrate. After removing photoresistive material, the semiconductor device package is built by encapsulating the signal conduits along with any semiconductor die and other parts of the package. The ends of the signal conduits are exposed and the signal conduits can then be used as through vias, providing signal-bearing pathways between interconnects or contacts on the bottom and top of the package, and electrical contacts of the semiconductor die. Using this method, signal conduits can be provided in a variety of geometric placings in the semiconductor device package.

For convenience of explanation, and not intended to be limiting, the present invention is described for semiconductor devices, but persons of skill in the art will understand that the present invention applies to any type of electronic or opto-electronic device that is substantially planar. Accordingly, such other types of devices including the non-limiting examples given below, are intended to be included in the terms “device,” “semiconductor device,” and “integrated circuit” whether singular or plural, and the terms “device,” “die,” and “chip” are intended to be substantially equivalent. Non-limiting examples of suitable devices are semiconductor integrated circuits, individual semiconductor devices, piezoelectric devices, solid-state filters, magnetic tunneling structures, integrated passive devices such as capacitors, resistors and inductors, and combinations and a raise of any and all of these types of devices and elements. Further, embodiments of the present invention do not depend upon the types of die or chips being used nor the materials of which they are constructed provided that such materials withstand the encapsulation process.

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

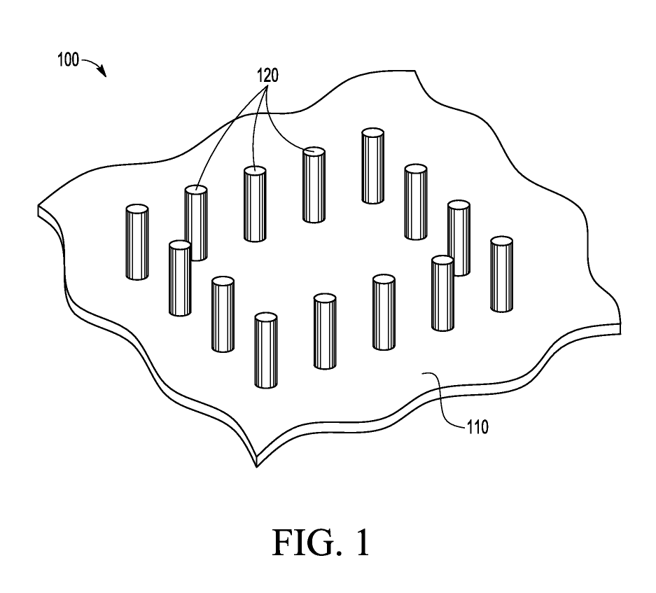

FIG. 1 is a simplified block diagram illustrating a perspective view of assembly 100 having signal conduits formed on a metal film or other substrate, in accord with one embodiment of the present invention. A portion of metal film or substrate 110 is shown with conductive signal conduits 120 formed on a major surface of the film or substrate. It should be understood that assembly 100 is one region of the film or substrate and that a larger area assembly can used to fabricate a panel (e.g., a grid layout). Metal film 110 can be made from a variety of materials standard in the art of semiconductor packaging and suitable to the application (e.g., copper, iron, zinc, nickel, magnesium, and the like, and alloys made therefrom). As will be discussed more fully below, signal conduits 120 can be formed from any material suitable to the application. Embodiments of the present invention form the signal conduits using a metal plating process.

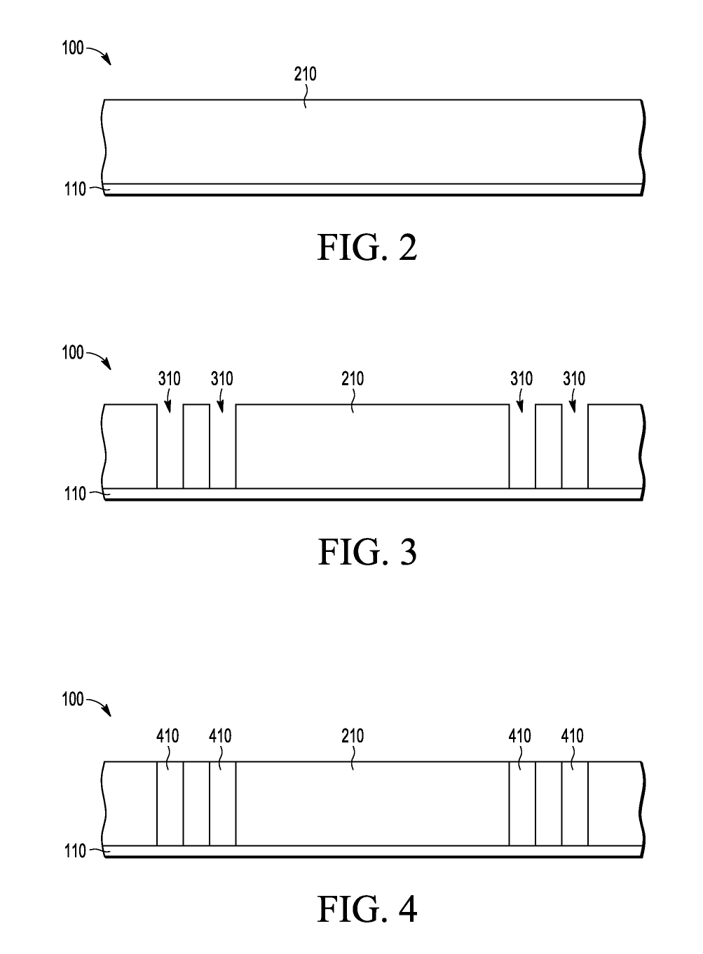

FIG. 2 is a simplified block diagram illustrating an example of a plating process for forming electrically-conductive signal conduits on assembly 100, in accord with one embodiment of the present invention. FIG. 2 is a cross sectional view of a portion of the assembly at a stage of processing. Film material/substrate 110 is provided and a photolithographic material layer 210 is deposited on the film material/substrate. Photolithographic material layer 210 should be deposited to a thickness sufficient to form the signal conduits that will ultimately be used as through vias in the semiconductor package. In typical applications, it can be desirable to have conductive through vias of 100 microns to 2 millimeters, depending upon the nature of the application. In one embodiment, the thickness of the photolithographic material layer is approximately 500 microns thick.

Photolithographic material layer 210 can be made from a variety of materials such as photoresist or a dry film lamination layer. The photolithographic materials chosen for the application should be sufficient to support formation of signal conduit features having aspect ratios of as much as 5:1 between height of the feature (or thickness of the photolithographic material layer) and diameter/width of the feature. That is, expected shape and dimensions of the signal conduit are maintained throughout the thickness of the photoresist. In one embodiment, signal conduit feature aspect ratios are approximately 3:1. Examples of photolithographic materials capable of supporting such aspect ratios include DUPONT MPF dry film and microlithographic polymer film or resist materials.

FIG. 3 is a simplified block diagram of assembly 100 at a later stage in processing, according to one embodiment of the present invention. Photolithographic material layer 210 is patterned through standard techniques to form columnar holes 310 in which the signal conduits will be formed. Holes 310 can have any cross-sectional shape desirable for the application.

FIG. 4 is a simplified block diagram illustrating the cross sectional view of assembly 100 at a later stage in processing, according to an embodiment of the present invention. Conductive signal conduits are formed by applying a plating layer 410 that forms the signal conduits in holes 310. Plating layer 310 can include generally any conductive material, such as, but not limited to, aluminum, copper, tantalum, titanium, tungsten, or any metal alloy, nitride or silicide thereof.

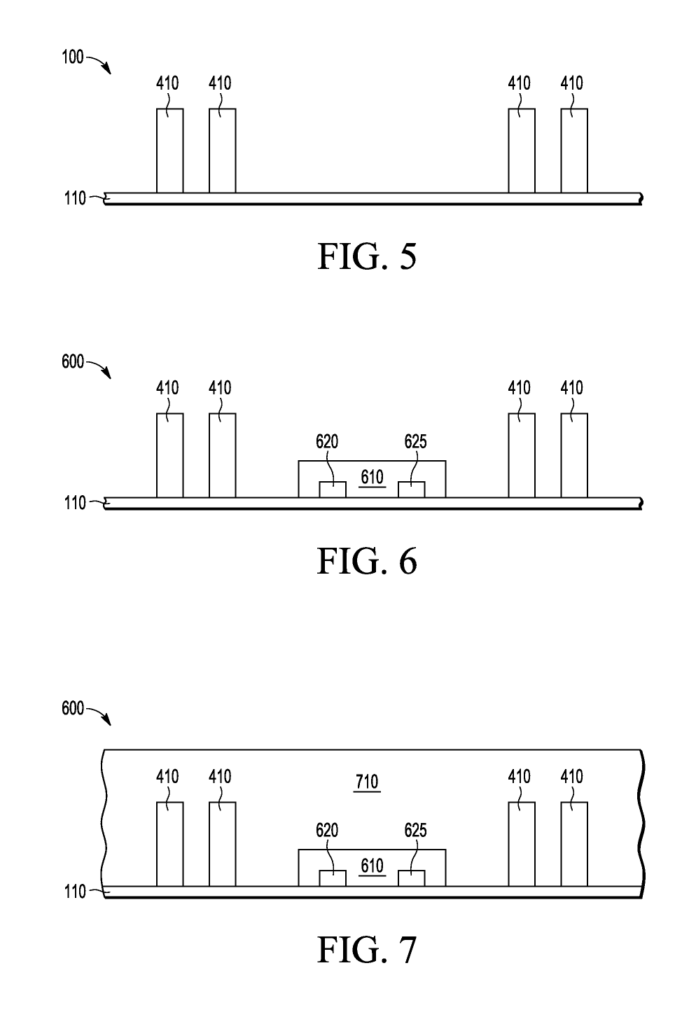

FIG. 5 is a simplified block diagram illustrating the cross sectional view of assembly 100 at a later stage in processing, according to an embodiment of the present invention. Subsequent to plating, a photoresist and/or dry film strip process is performed to remove the photolithographic material layer. Subsequent to stripping, metal film/substrate 110 and signal conduits 410 (as formed from the plating process) remain. The assembly illustrated in FIG. 5 as a cross-section can resemble assembly 100 illustrated in FIG. 1. Subsequent processing can now include associating the assembly with various device die in an encapsulation process.

It should be understood that the geometries and configurations provided herein are made by way of example and are not intended to limit the nature or applications of embodiments of the present invention.

FIG. 6 is a simplified block diagram illustrating a cross-sectional view of a device structure 600 at a stage in one example of processing, according to an embodiment of the present invention. Assembly 100 with metal film/substrate 110 and signal conduits 410 are provided. At least a die 610 is affixed active surface face down on metal film/substrate 110. The “active surface” of die 610 is a surface of the die having bond pads 620 and 625. Die 610 can be attached to metal film/substrate 110 using an adhesive layer that can withstand the packaging processing without becoming permanently fixed in place, since at a later point in processing the adhesive (and metal film/substrate 110) will be separated from the package.

It should further be noted that embodiments of the present invention do not depend on the exact nature of the components incorporated in the device structure (e.g., die 610). The component can be, for example, integrated circuits, individual devices, filters, magnetostrictive devices, electro-optical devices, electro-acoustic devices, integrated passive devices such as resistors, capacitors and inductors, or other types of elements and combinations thereof, and can be formed of any materials able to withstand the encapsulation process. Non-limiting examples of materials are various organic and inorganic semiconductors, type IV, III-V and II-VI materials, glasses, ceramics, metals, semi-metals, inter-metallics and so forth.

FIG. 7 is a simplified block diagram illustrating the cross sectional view of device structure 600 at a later stage in the processing example. A molding material is applied to the structures affixed to metal film/substrate 110 (e.g., signal conduits 410 and die 610), forming an encapsulant 710 that encapsulates the structures within the molding material and forms a panel. The molding material can be any appropriate encapsulant including, for example, silica-filled epoxy molding compounds, plastic encapsulation resins, and other polymeric materials such as silicones, polyimides, phenolics, and polyurethanes. The molding material can be applied by a variety of standard processing techniques used in encapsulation including, for example, printing, pressure molding and spin application. Once the molding material is applied, the panel can be cured by exposing the materials to certain temperatures for a period of time, or by applying curing agents, or both. In a typical encapsulation process, a depth of encapsulant 710 can exceed a maximum height of structures embedded in the molding material (e.g., the height of signal conduits 410 as illustrated in FIG. 7).

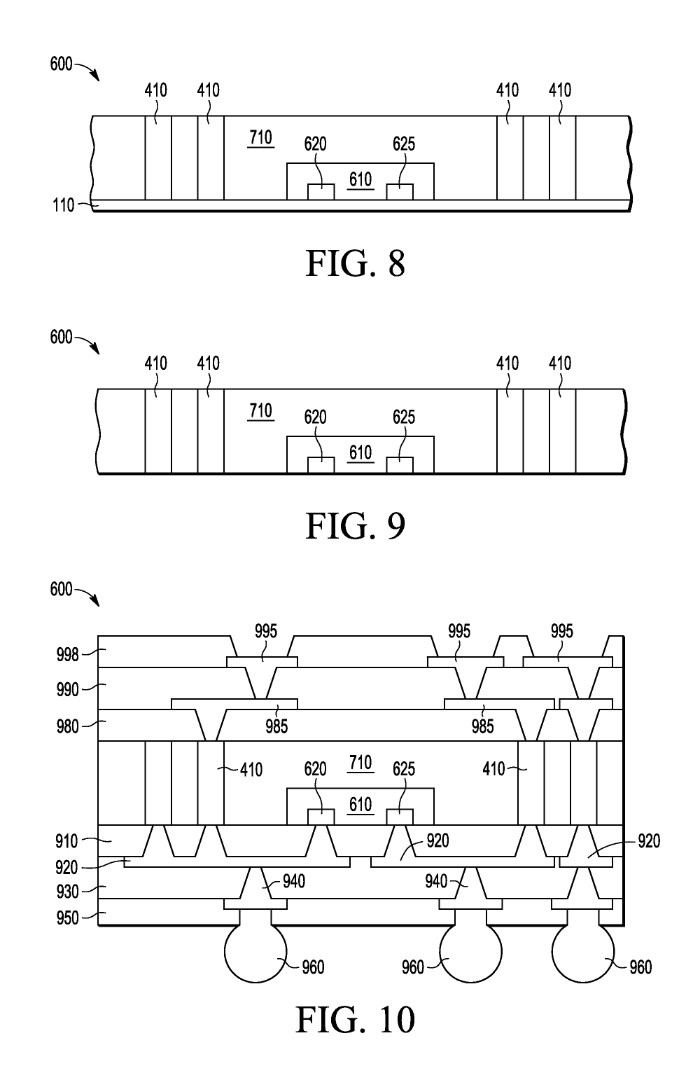

FIG. 8 is a simplified block diagram illustrating the cross sectional view of device structure 600 at a later stage in the processing example. Encapsulant 710 is reduced in thickness to expose the ends of signal conduits 410. This reduction in thickness of the encapsulant and exposing of the ends of the signal conduits can be performed by a grinding process, chemical etching, laser ablation, or other conventional techniques (e.g., backgrinding). Alternatively, the encapsulant can be formed to the appropriate thickness during the encapsulation process by, for example, compression molding with film applied to control encapsulant thickness to that of the signal conduits or thinner (i.e., forming a stud-type structure above the surface of the panel back side).

FIG. 9 is a simplified block diagram illustrating the cross sectional view of device structure 600 at a later stage in the processing example. The metal film/substrate is removed from the encapsulated panel. Removal of metal film, for example, can be performed using a metal etch process known in the art. Once removed, the side of the panel previously attached to the metal film/substrate can be cleaned to remove any excess material remaining attached to the encapsulated panel. This process of release and clean exposes all of the contacts on the bottom side of the panel, including the bottom of signal conduits 410 and bond pads 620 and 625. At this point, it can be seen that signal conduits 410 form conductive vias between the top major surface of the encapsulated panel to the bottom major surface. These through vias can be used to enable electrical connection between interconnect structures or pads formed on the bottom and top of packages formed from the panel, thereby allowing package-on-package implementations.

An alternative to removal of all of a metal film 110 is to perform a selective etch process, thereby leaving portions of the metal film to form a lead frame structure that can be used in formation of interconnect structures and the like. Photolithographic techniques can be employed to perform the selective etching (e.g., deposition and patterning of photolithographic layers on the metal film layer).

FIG. 10 is a simplified block diagram illustrating the cross sectional view of device structure 600 after buildup, ball placement and singulation. Processing providing the various layers illustrated in FIG. 10 can be provided by standard techniques used in semiconductor packaging.

An insulating layer 910 can be deposited over the bottom surface of the encapsulated die, signal conduits and encapsulation molding material. Insulating layer 910 can be made from organic polymers, for example, in liquid or dry film and can include a wide range of other materials used for interlayer dielectrics as known in the art (e.g., silicon dioxide, silicon nitride, silicon oxynitride, or any combination of such layers providing electrical isolation). Insulating layer 910 can be patterned to expose bonding pads 620 and 625, as well as the through vias formed by signal conduits 410.

A conductive layer 920 can then be formed to provide an interconnect between the bonding pads and leads. Conductive layer 920 can include materials such as metal, metal alloy, doped semiconductor, semi-metals, or combinations thereof as known in the art (e.g., amorphous silicon, doped polysilicon, aluminum, copper, tantalum, titanium, tungsten, or any metal alloy, nitride or silicide). Through the use of a conductive layer, any number of bonding pads can be interconnected in any combination to the same or other die and to the through vias formed by electrically conductive signal conduits 410. The interconnect illustrated in FIG. 9 is provided only by way of example, and it should be realized that the interconnects formed by conductive layer 920 and other conductive layers discussed below can extend not only across the page as illustrated but also into and above the page.

An additional interconnect layer can be provided by forming additional insulating layers (e.g. insulating layer 930) and patterning those insulating layers to receive additional conductive layers (e.g., conductive layer 940). The range of materials that can be used for subsequent insulating layers and conductive layers can include those listed for insulating layer 910 and conductive layer 920, and each type of layer can be the same or different materials as required by the nature of the application. Further, as illustrated, a set of conductive ball connectors can be provided by forming insulating layer 950, patterning that layer to expose pads formed in conductive layer 940, and forming and placing conductive balls 960 using standard techniques and materials.

FIG. 10 illustrates an example of a double-sided semiconductor package, in which an interconnect is provided on the top side of the package. Vias formed by electrically conductive signal conduits 410 allow for connections to be made between the bottom side interconnect and the top side interconnect. Again, the top side interconnect can be formed by standard techniques. For example, an insulating layer 980 can be formed over the top side surface of the signal conduits and encapsulation molding material. The insulating layer can be patterned to expose the top end of the vias formed by signal conduits 410. A conductive layer 985 can then be used to form an interconnect, which can be patterned and etched as required by the application. Subsequent insulating layers (e.g. insulating layer 990) and conductive layers (e.g. conductive layer 995) can be formed as required by the application. An additional insulation layer 998 can be formed to define a pattern to receive components on the top side of the package.

After buildup of top and bottom side interconnects has been performed, individual semiconductor packages can be separated from the panel using a singulation process.

Alternatively, there can be no top side build up of the package. Components can be mounted directly onto the top side of the package and electrically connected to the top ends of the through vias formed by signal conduits 410.

Embodiments of the present invention are not limited to the particular type of process illustrated in the figures. As shown, embodiments of the present invention are used in a fan-out wafer level package, (e.g. redistributed chip packaging process (RCP)), but embodiments of the present invention are not limited to fan-out wafer level package. For example, the signal conduits of the present invention can be incorporated in BBC packages. It should be realized, however, that steps discussed above may require modification for different types of processes.

The signal conduits of the present invention allow for forming through vias prior to encapsulation. Conduits can be formed in a manner before a pick and place process. Other components, such as die, can be placed at a later stage. This allows for great flexibility in through via placement. The signal conduits are embedded in the package during the encapsulation process. The signal conduits are then exposed during standard back grinding of the encapsulant or can be exposed using alternate methods such as laser ablation or controlling the encapsulant to the appropriate thickness with, for example, compression molding. Subsequent processing (e.g., buildup) of the encapsulated device can use the signal conduits as through package connections (e.g. through vias).

The processes of the present invention save the need for post-encapsulation via drilling and filling steps. The process provides consistent quality signal paths through the depth of the package that do not depend upon a quality of a fill operation.

By now it should be appreciated that one embodiment of the present invention provides a method for packaging an electronic device assembly that includes providing a substrate, forming one or more signal conduits on the substrate in which a first end of each signal conduit contacts the substrate, forming an encapsulant over and around sides of the one or more signal conduits, exposing a second end of each signal conduit wherein each signal conduit forms a conductive via through the electronic device assembly.

One aspect of the above embodiment further includes exposing the first end of each signal conduit of the one or more signal conduits by removing the substrate from the one or more signal conduits and the encapsulant. A further aspect provides for removing the substrate by etching the substrate when the substrate is a metal film.

In another aspect of the above embodiment, forming the one or more signal conduits further includes forming a photoresist layer on the substrate, forming one or more openings in the photoresist layer corresponding to where the one or more signal conduits are desired, depositing a conductive material in the openings in the photoresist layer, and stripping the photoresist layer from the substrate. In another aspect of the above embodiment, exposing the second end of each signal conduit further includes controlling forming the encapsulant to a thickness less than or equal to a length of the signal conduits.

Another aspect of the above embodiment further includes placing an electronic device on the substrate in an area of the electronic device assembly, where forming the encapsulant further includes forming the encapsulant over and around sides of the first electronic device. A further aspect includes removing the substrate from the encapsulant, the signal conduits, and the electronic device after forming the encapsulant, where this removing exposes the first end of the one or more signal conduits and electrical contacts of the electronic device. A still further aspect includes forming, after removing the substrate, a first interconnect structure on a first side of the electronic device assembly wherein the first interconnect structure couples a contact on the electronic device to a signal conduit.

Another aspect of the above embodiment further includes forming, after exposing the second end of the one or more signal conduits, and interconnect structure on a side of the electronic device assembly having the second end of the signal conduits, wherein the interconnect structure is coupled to one or more of the signal conduits. In a further aspect, the second interconnect structure is made to receive a second electronic device assembly.

Another aspect of the above embodiment further includes placing a second electronic device assembly on the exposed second end of one or more signal conduits such that the second electronic device assembly is electrically coupled to the one or more signal conduits.

Another embodiment of the present invention provides an electronic device assembly that includes an electronic device, one or more conductive vias extending from the top surface of the package device assembly to the bottom surface of the package device assembly, and encapsulant over and around the electronic device and around the conductive vias and forming an encapsulated region of the package device assembly. The one or more conductive vias are formed using corresponding signal conduits and each signal conduit is formed before encapsulating the electronic device and signal conduits. Forming each signal conduit includes patterning openings in a photoresist layer on a substrate, depositing a conductive material in the openings in the photoresist layer, and stripping the photoresist layer from the substrate.

In one aspect of the above embodiment, the package device assembly further includes a first interconnect structure on a first side of the electronic device assembly, wherein the first interconnect structure couples a contact on the first electronic device to a signal conduit. In a further aspect, the packaged device assembly further includes a second interconnect structure on a second side of the electronic device assembly, where the second interconnect structure is coupled to the signal conduit and the signal conduit electrically couples the first interconnect structure with the second interconnect structure. In yet a further aspect, the package device assembly is made such that the second interconnect structure can receive a second electronic device assembly.

Another embodiment of the present invention provides a method for packaging an electronic device assembly that includes forming a photoresist layer on a metal film, forming one or more openings in the photoresist layer extending from the surface of the photoresist layer to the metal film, depositing a conductive material in the openings in the photoresist layer to form corresponding signal conduits, stripping the photoresist layer from the metal film, and forming an encapsulant over and around sides of the one or more signal conduits and over the metal film.

One aspect of the above embodiment further includes placing an electronic device on the metal film in an area for the electronic device assembly after the stripping of the photoresist layer from the metal film, and forming the encapsulant over and around sides of the electronic device. A further aspect includes removing the metal film to expose a first end of the one or more signal conduits and an active surface of the electronic device. A still further aspect includes exposing a second end of the one or more signal conduits, where exposing includes removing a portion of the encapsulant from the electronic device assembly. In yet a further aspect, removing the portion of the encapsulant includes one of grinding the encapsulant from the electronic device assembly to a depth at least matching the second end of the signal conduits or laser ablating the encapsulant from the electronic device assembly to a depth at least matching the second end of the signal conduits.

Because the apparatus implementing the present invention is, for the most part, composed of electronic components and circuits known to those skilled in the art, circuit details are not explained in any greater extent than that considered necessary as illustrated above, for the understanding and appreciation of the underlying concepts of the present invention and in order not to obfuscate or distract from the teachings of the present invention.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method for packaging an electronic device assembly, the method comprising:
providing a substrate;
forming one or more signal conduits on the substrate, wherein a first end of each signal conduit contacts the substrate;
forming an encapsulant over and around sides of the one or more signal conduits; and
exposing a second end of each signal conduit of the one or more signal conduits, wherein each signal conduit forms a conductive via through the electronic device assembly.

2. The method of claim 1 further comprising:
exposing the first end of each signal conduit of the one or more signal conduits by removing the substrate from the one or more signal conduits and the encapsulant.

3. The method of claim 2, wherein
said removing the substrate comprises etching the substrate, and
the substrate is a metal film.

4. The method of claim 1 wherein said forming the one or more signal conduits comprises:
forming a photoresist layer on the substrate;
forming one or more openings in the photoresist layer corresponding to where the one or more signal conduits are desired;
depositing a conductive material in the openings in the photoresist layer; and
stripping the photoresist layer from the substrate.

5. The method of claim 1 wherein said exposing the second end of each signal conduit comprises controlling said forming the encapsulant to a thickness less than or equal to a length of the signal conduits.

6. The method of claim 1 further comprising:
placing a first electronic device on the substrate in an area for the electronic device assembly, wherein
said forming the encapsulant further comprises forming the encapsulant over and around sides of the first electronic device.

7. The method of claim 6 further comprising:
removing the substrate from the encapsulant, the one or more signal conduits, and the first electronic device, after said forming the encapsulant, wherein
said removing exposes the first end of the one or more signal conduits and electrical contacts of the first electronic device.

8. The method of claim 7 further comprising:
forming, after said removing the substrate, a first interconnect structure on a first side of the electronic device assembly, wherein the first interconnect structure couples a first contact on the first electronic device to a signal conduit of the one or more signal conduits.

9. The method of claim 1 further comprising:
forming, after said exposing the second end of the one or more signal conduits, an interconnect structure on a side of the electronic device assembly having the second end of the signal conduits, wherein the interconnect structure is coupled to one or more of the signal conduits.

10. The method of claim 9 wherein the second interconnect structure is configured to receive a second electronic device assembly.

11. The method of claim 1 further comprising:
placing a second electronic device assembly on the exposed second end of one or more signal conduits such that the second electronic device assembly is electrically coupled to the one or more signal conduits.

12. A packaged device assembly comprising:
an electronic device;
one or more conductive vias extending from a top surface of the packaged device assembly to a bottom surface of the packaged device assembly; and
encapsulant over and around the electronic device and around the conductive vias and forming an encapsulated region of the packaged device assembly, wherein
the one or more conductive vias are formed using corresponding signal conduits, and
each signal conduit is formed before encapsulating the electronic device and signal conduits, and
forming each signal conduit comprises patterning openings in a photoresist layer on a substrate, depositing a conductive material in the openings in the photoresist layer, and stripping the photoresist layer from the substrate.

13. The packaged device assembly of claim 12 further comprising:
a first interconnect structure on a first side of the electronic device assembly, wherein the first interconnect structure couples a first contact on the first electronic device to a signal conduit of the one or more signal conduits.

14. The packaged device assembly of claim 13 further comprising:
a second interconnect structure on a second side of the electronic device assembly, wherein the second interconnect structure is coupled to the signal conduit and the signal conduit electrically couples the first interconnect structure and the second interconnect structure.

15. The packaged device assembly of claim 14 wherein the second interconnect structure is configured to receive a second electronic device assembly.

16. A method for packaging an electronic device assembly, the method comprising:
forming a photoresist layer on a metal film;
forming one or more openings in the photoresist layer, wherein the one or more openings extend from the surface of the photoresist layer to the metal film;
depositing a conductive material in the openings in the photoresist layer to form corresponding one or more signal conduits;
stripping the photoresist layer from the metal film; and
forming an encapsulant over and around sides of the one or more signal conduits and over the metal film.

17. The method of claim 16 further comprising:
placing an electronic device on the metal film in an area for the electronic device assembly, after said stripping the photoresist layer from the metal film; and
forming the encapsulant over and around sides of the electronic device.

18. The method of claim 17 further comprising:
removing the metal film to expose a first end of the one or more signal conduits and an active surface of the electronic device.

19. The method of claim 18 further comprising:
exposing a second end of the one or more signal conduits, wherein said exposing the second end comprises removing a portion of the encapsulant from the electronic device assembly.

20. The method of claim 19 wherein said removing the portion of the encapsulant comprises one of:
grinding the encapsulant from the electronic device assembly to a depth at least matching the second end of the signal conduits; and
laser ablating the encapsulant from the electronic device assembly to a depth at least matching the second end of the signal conduits.
